(19) United States
(12) Patent Application Publication
(10) Pub. No.: US 2022/0122841 A1
(43) Pub. Date: Apr. 21, 2022

(54) METHODS FOR DEPOSITING GAP-FILLING FLUIDS AND RELATED SYSTEMS AND DEVICES

(71) Applicant: ASM IP HOLDING B.V., Almere (NL)

(72) Inventors: Timothee Blanquart, Oud-Heverlee (BE); Takahiro Onuma, Tokyo (JP); Shinya Yoshimoto, Tokyo (JP); Charles Dezelah, Helsinki (FI); Jihee Jeon, Leuven (BE)

(21) Appl. No.: 17/451,280

(22) Filed: Oct. 18, 2021

Related U.S. Application Data
(60) Provisional application No. 63/094,586, filed on Oct. 21, 2020.
(60) Provisional application No. 63/200,704, filed on Mar. 23, 2021.

(51) Int. Cl. H01L 21/02; C23C 16/455; C23C 16/34

(52) U.S. Cl. CPC H01L 21/02222; H01L 21/0217; H01J 37/32724; C23C 16/45536; C23C 16/345; H01L 21/02274

(57) ABSTRACT

Methods and systems for manufacturing a structure comprising a substrate are provided herein. In some embodiments, the substrate comprises a plurality of recesses. The recesses may be at least partially filled with a gap filling fluid. The gap filling fluid may comprise an Si—N bond.

### CROSS REFERENCE TO RELATED APPLICATIONS

This application claims the priority benefit under 35 U.S.C. § 119(e) of U.S. Provisional Application No. 63/094,586, filed Oct. 21, 2020, entitled “METHODS FOR DEPOSITING GAP-FILLING FLUIDS AND RELATED SYSTEMS AND DEVICES”, and U.S. Provisional Application No. 63/200,704, filed Mar. 23, 2021, entitled ‘METHODS FOR DEPOSITING GAP-FILLING FLUIDS AND RELATED SYSTEMS AND DEVICES”. The entire disclosure of each of the foregoing applications is incorporated herein by reference.

### FIELD OF THE INVENTION

The present disclosure generally relates to methods and systems suitable for forming electronic devices. More particularly, the disclosure relates to methods and systems that can be used for depositing a material in gaps, trenches, and the like by plasma-assisted deposition.

### BACKGROUND

The scaling of semiconductor devices has led to significant improvements in speed and density of integrated circuits. However, with miniaturization of wiring pitch of large-scale integration devices, void-free filling of high aspect ratio trenches (e.g., trenches having an aspect ratio of three or higher) becomes increasingly difficult due to limitations of existing deposition processes. Therefore, there remains a need for processes that efficiently fill high aspect ratio features, e.g., gaps such as trenches on semiconductor substrates.

Any discussion, including discussion of problems and solutions, set forth in this section has been included in this disclosure solely for the purpose of providing a context for the present disclosure. Such discussion should not be taken as an admission that any or all of the invention was previously known or otherwise constitutes prior ar.

### SUMMARY

Various embodiments of the present disclosure relate to gap filling methods, to structures and devices formed using such methods, and to apparatuses for performing the methods and/or for forming the structure and/or devices. The ways in which various embodiments of the present disclosure address drawbacks of prior methods and systems are discussed in more detail below.

Thus, described herein is a method of filling a gap comprising: introducing in a reactor chamber a substrate provided with a gap; introducing a precursor into the reactor chamber, the precursor comprising silicon, nitrogen, and hydrogen; introducing a co-reactant into the reactor chamber, wherein the co-reactant is selected from nitrogen, hydrogen, ammonia, hydrazine, one or more noble gasses, and mixtures thereof; and, generating a plasma in the reactor chamber; whereby the precursor and the co-reactant react in the presence of the plasma to form a gap filling fluid that at least partially fills the gap, the gap filling fluid comprising silicon, nitrogen, and hydrogen.

In some embodiments, the precursor consists of silicon, nitrogen, and hydrogen; and the gap filling fluid consists of silicon, nitrogen, and hydrogen.

In some embodiments, the precursor further comprises one or more halogens, and the gap filling fluid further comprises one or more halogens.

In some embodiments, the precursor consists of silicon, nitrogen, hydrogen, and one or more halogens; and the gap filling fluid consists of silicon, nitrogen, hydrogen, and one or more halogens.

In some embodiments, described herein is a method of filling a gap. The method comprises introducing in a reactor chamber a substrate provided with a gap. The method further comprises introducing a precursor into the reactor chamber. The precursor consists of silicon, nitrogen, and hydrogen, and optionally one or more halogens. The method further comprises introducing a co-reactant into the reactor chamber. The co-reactant is selected from nitrogen, hydrogen, ammonia, hydrazine, one or more noble gasses, and mixtures thereof. The method further comprises introducing a plasma in the reactor chamber. Thus, the precursor and the co-reactant react to form a gap filling fluid that at least partially fills the gap. It shall be understood that the gap filling fluid substantially consists of silicon, nitrogen, hydrogen, and optionally one or more halogens.

In some embodiments, the precursor consists of silicon, nitrogen, and hydrogen.

In some embodiments, the precursor can be represented by a chemical formula according to formula (1)

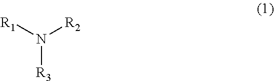

wherein R₁, R₂, and R₃ are independently selected from SiH₃, SiH₂X, SiHXY, SiX₂Y, and SiX₃, wherein X is a first halogen, and wherein Y is a second halogen.

In some embodiments, at least one of R₁, R₂, and R₃ is SiH₃.

In some embodiments, the precursor can be represented by a chemical formula according to formula (2)

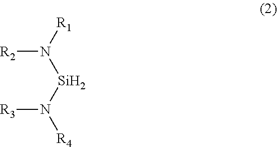

wherein R₁, R₂, R₃, and R₄ are independently selected from H, SiH₃, SiH₂X, SiHXY, SiX₂Y, and SiX₃, wherein X is a first halogen, and wherein Y is a second halogen.

In some embodiments, at least one of R₁, R₂, R₃, and R₄ is SiH₃.

In some embodiments, the precursor can be represented by a chemical formula according to formula (3)

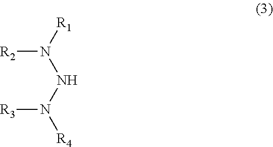

wherein R₁, R₂, R₃, and R₄ are independently selected from SiH₃, SiH₂X, SiHXY, SiX₂Y, and SiX₃, wherein X is a first halogen, and wherein Y is a second halogen.

In some embodiments, at least one of R₁, R₂, R₃, and/or R₄ is SiH₃.

In some embodiments, the precursor is a hydrosilazane.

In some embodiments, the precursor is a cyclohydrosilazane.

In some embodiments, the precursor can be represented by a chemical formula according to formula (4)

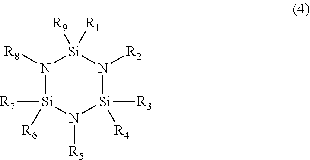

wherein R₁, R₂, R₃, R₄, R₅, R₆, R₇, R₈, and R₉ are independently selected from the list consisting of H, X, Y, NH₂, SiH₃, SiH₂X, SiHXY, SiX₂Y, and SiX₃; wherein X is a first halogen, and wherein Y is a second halogen.

In some embodiments, at least one of R₁, R₂, R₃, R₄, R₅, R₆, R₇, R₈, and R₉ is H.

In some embodiments, the precursor can be represented by a chemical formula according to formula (5)

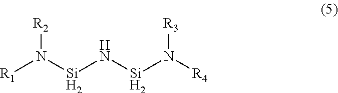

wherein R₁, R₂, R₃, and R₄ are independently selected from SiH₃, SiH₂X, SiHXY, SiX₂Y, and SiX₃, wherein X is a first halogen, and wherein Y is a second halogen.

In some embodiments, R₁, R₂, R₃, and R₄ are SiH₃.

In some embodiments, the co-reactant comprises nitrogen and/or ammonia.

In some embodiments, the co-reactant comprises a noble gas.

In some embodiments, the noble gas is selected from the list consisting of He, Ne, Ar, and Kr.

In some embodiments, the noble gas is Ar.

In some embodiments, the reactor chamber is, at least during the method, at a pressure of at least 500 Pa to at most 1500 Pa and at a temperature of at least 50° C. to at most 150° C.

In some embodiments, the reactor chamber is, at least during the method, at a pressure of at least 600 Pa to at most 1200 Pa.

In some embodiments, the reactor chamber is, at least during the method, at a temperature of at least 70° C. to at most 90° C.

In some embodiments, introducing the precursor and the co-reactant occurs at least partially simultaneously.

In some embodiments, the co-reactant is provided continuously, the precursor is provided in a plurality of precursor pulses, the plasma is provided in a plurality of plasma pulses, and individual precursor pulses and individual plasma pulses are separated by purge steps.

In some embodiments, the precursor does not contain any oxygen.

In some embodiments, the precursor does not contain any halogens.

In some embodiments, no gasses other than the precursor, Ar, or He are introduced into the reactor chamber during the steps of introducing the precursor, the co-reactant, and the plasma into the reaction chamber.

In some embodiments, the substrate comprises a semiconductor.

In some embodiments, the method includes entirely filling the plurality of recesses with a gap filling fluid.

In some embodiments, the method comprises curing the gap filling fluid.

In some embodiments, the step of curing involves exposing the gap filling fluid to a direct plasma and the method for filling a gap comprises a plurality of cycles in which gap filling fluid deposition and plasma treatment steps are alternated.

In some embodiments, the step of curing involves exposing the gap filling fluid to an indirect plasma after the gap has been filled with the gap filling fluid.

In some embodiments, the step of curing involves exposing the gap filling fluid to a noble gas plasma.

In some embodiments, the step of curing involves exposing the gap filling fluid to a micro pulsed plasma involving the sequential application of a plurality plasma on and plasma off pulses.

In some embodiments, the substrate is a 300 mm silicon wafer, and a plasma gas flow rate of at least 5.0 slm is maintained during the micro pulsed plasma.

Further provided is a system configured to perform a method as described herein.

Further provided is a system comprising: one or more reaction chambers; a gas injection system fluidly coupled to at least one of the one or more reaction chambers; a first gas source for introducing a precursor and optionally a carrier gas in the reactor chamber; a second gas source for introducing a mixture of one or more further gasses into the reactor chamber; an exhaust; and a controller. The controller is configured to control gas flow into the gas injection system and for causing the system to carry out a method as described herein.

These and other embodiments will become readily apparent to those skilled in the art from the following detailed description of certain embodiments having reference to the attached figures. The invention is not limited to any particular embodiments disclosed.

### BRIEF DESCRIPTION OF THE FIGURES

A more complete understanding of the embodiments of the present disclosure may be derived by referring to the detailed description and claims when considered in connection with the following illustrative figures.

FIG. 1 is a schematic representation of a plasma-enhanced atomic layer deposition (PEALD) apparatus suitable for depositing a structure and/or for performing a method in accordance with at least one embodiment of the present disclosure.

FIG. 2 illustrates a schematic representation of a precursor supply system using a flow-pass system (FPS) usable in accordance with at least one embodiment of the present disclosure.

FIG. 3 shows transmission electron micrographs of gaps filled with gap filling fluids deposited according to at least one embodiment of the methods of the present disclosure.

FIG. 4 shows transmission electron micrographs of gaps filled with gap filling fluids deposited according to at least one embodiment of the present disclosure.

FIG. 5 illustrates an example film flowability model/window for a flowable gap fill film according to at least one embodiment of the present disclosure.

FIG. 6 illustrates a composition analysis performed by Fourier Transformed Infrared Spectroscopy (FTIR) of a capped and uncapped film sample according to at least one embodiment of the present disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods, structures, devices, and systems provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, a multi-port injection system, other gas distribution device, or the like, can be used for, e.g., sealing the reaction space, and can include a seal gas, such as a rare gas. The terms “rare gas” and “noble gas” as used herein may be used interchangeably. In some cases, the term “precursor” can refer to a compound that participates in the chemical reaction that produces another compound, and particularly to a compound that constitutes a film matrix or a main skeleton of a film; the term “reactant” may be used interchangeably with the term precursor.

In some embodiments, the term “co-reactant” refers to a gas which can react and/or interact with a precursor in order to form a flowable gap fill layer as described herein. The co-reactant may activate precursor oligomerization. The co-reactant may be a catalyst. The co-reactant does not necessarily have to be incorporated in the gap filling fluid, which is formed, though the co-reactant does interact with the precursor during formation of the gap filling fluid. In other words, in some embodiments the co-reactant is incorporated in the gap filling fluid whereas in other embodiments, the co-reactant is not incorporated in the gap filling fluid. Possible co-reactants include noble gasses, which can be brought in an excited state, in particular an excited state such as ion and/or radical induced by means of a plasma, such as He and Ar, as well as other gasses such as N₂, H₂, and NH₃. Alternative expressions for the term “co-reactant” as used herein may include “reactant”, “gas mixture”, “one or more further gasses”, and “gas mixture comprising one or more further gasses”.

In some embodiments, the term “substrate” can refer to any underlying material or materials that can be used to form a device, a circuit, or a film, or upon which a device, a circuit, or a film can be formed. In some embodiments, the substrate comprises a semiconductor. A substrate can include a bulk material, such as silicon (e.g., single-crystal silicon), other Group IV materials, such as germanium, or other semiconductor materials, such as a Group II-VI or Group III-V semiconductor and can include one or more layers overlying or underlying the bulk material.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

As used herein, the term “comprising” indicates that certain features are included, but that it does not exclude the presence of other features, as long as they do not render the claim unworkable. In some embodiments, the term “comprising” includes “consisting”.

As used herein, the term “consisting” indicates that no further features are present in the apparatus/method/product apart from the ones following said wording. When the term “consisting” is used referring to a chemical compound, substance, or composition of matter, it indicates that the chemical compound, substance, or composition of matter only contains the components which are listed. This notwithstanding, the chemical compound, substance, or composition of matter may, in some embodiments, comprise other components as trace elements or impurities, apart from the components which are listed.

In some embodiments, the term “gap filling fluid”, also referred to as “flowable gap fill”, may refer to an oligomer which is liquid under the conditions under which is deposited on a substrate, and which has the capability to cross link and for a solid film.

In some embodiments, the term “filling capability” may refer to a capability of filling a gap substantially without voids (e.g., no void having a size of approximately 5 nm or greater in diameter) and seams (e.g., no seam having a length of approximately 5 nm or greater), wherein seamless/void less bottom-up growth of a layer is observed. In some embodiments, the growth at a bottom of a gap may be at least approximately 1.5 times faster than growth on sidewalls of the gap and on a top surface having the gap. A film having filling capability can be referred to as “flowable film” or “viscous film”. The flowable or viscous behavior of a film is often manifested as a concave surface at a bottom of a trench.

In this disclosure, a recess between adjacent protruding structures and any other recess pattern may be referred to as a “trench”. That is, a trench may refer to any recess pattern including a hole/via. A trench can have, in some embodiments, a width of about 5 nm to about 150 nm, or about 30 nm to about 50 nm, or about 5 nm to about 10 nm, or about 10 nm to about 20 nm, or about 20 nm to about 30 nm, or about 50 nm to about 100 nm, or about 100 nm to about 150 nm, or any value between the aforementioned values. When a trench has a length that is substantially the same as its width, it can be referred to as a hole or a via. Holes or vias typically have a width of about 20 nm to about 100 nm. In some embodiments, a trench has a depth of about 30 nm to about 100 nm, and typically of about 40 nm to about 60 nm. In some embodiments, a trench has an aspect ratio of about 2 to about 10, and typically of about 2 to about 5. The dimensions of the trench may vary depending on process conditions, film composition, intended application, etc.

Described herein is a method for filling a gap by means of a gap filling fluid comprising silicon and nitrogen. Also provided are films resulting from such methods, and structures including such films. In some embodiments, the filling capability can be accomplished by forming a viscous material in a gas phase by striking, for example, a noble gas, N₂ and/or NH₃ plasma, in a chamber filled with a volatile precursor that can be polymerized within certain parameter ranges. Optionally the gas phase comprises a further gas apart from the precursor, and a noble gas, N₂ and/or NH₃, for example H₂.

The gap filling fluid can be applied to various semiconductor devices including, but not limited to, cell isolation in 3D cross point memory devices, self-aligned via, dummy gate, reverse tone patterning, PC RAM isolation, cut hard mask, and DRAM storage node contact (SNC) isolation.

Thus, described herein are methods of filling a gap. A gap in a substrate may refer to a patterned recess or trench in a substrate. In some embodiments, such a method comprises introducing a substrate in a reactor chamber. The substrate is provided with a gap. When the substrate has been introduced into the reaction chamber, a precursor is introduced in the reaction chamber. Suitable precursors consist of silicon, nitrogen, and hydrogen, and optionally one or more halogens. In other words, suitable precursors comprise compounds that contain no other atoms apart from silicon atoms, nitrogen atoms, hydrogen atoms, and optionally one or more halogens. The method further comprises introducing a co-reactant in the reaction chamber. The method further comprises igniting a plasma in the reaction chamber when both precursor and co-reactant are present in the reaction chamber. Then, the precursor and the co-reactant react to form a gap filling fluid that at least partially fills the gap. The gap filling fluid consists of silicon, nitrogen, hydrogen, and optionally one or more halogens. In other words, in some embodiments, the gap filling fluid consists of silicon, nitrogen, and hydrogen; whereas in other embodiments, the gap filling fluid consists of silicon, nitrogen, hydrogen, and one or more halogens. It shall be understood that the co-reactant is not necessarily incorporated in the gap filling fluid which is deposited. Thus, in some embodiments the co-reactant is incorporated in the gap filling fluid whereas in other embodiments, the co-reactant is not incorporated in the gap filling fluid. For example, when a noble gas such as argon is used as a co-reactant, the argon is not substantially incorporated in the gap filling fluid.

In some embodiments, described herein is a method of filling a gap comprising: introducing in a reactor chamber a substrate provided with a gap; introducing a precursor into the reactor chamber, the precursor comprising silicon, nitrogen, and hydrogen; introducing a co-reactant into the reactor chamber, wherein the co-reactant is selected from nitrogen, hydrogen, ammonia, hydrazine, one or more noble gasses, and mixtures thereof; and, generating a plasma in the reactor chamber; whereby the precursor and the co-reactant react in the presence of the plasma to form a gap filling fluid that at least partially fills the gap, the gap filling fluid comprising silicon, nitrogen, and hydrogen.

In some embodiments, the precursor consists of silicon, nitrogen, and hydrogen; and the gap filling fluid consists of silicon, nitrogen, and hydrogen. In some embodiments, the precursor further comprises one or more halogens, and the gap filling fluid further comprises one or more halogens. In some embodiments, the precursor consists of silicon, nitrogen, hydrogen, and one or more halogens; and the gap filling fluid consists of silicon, nitrogen, hydrogen, and one or more halogens. It shall be understood that, when the gap filling fluid consists of certain components, other components may, in some embodiments, still be present in small quantities, e.g., as contaminants.

In some embodiments, the gap is entirely filled with the gap filling fluid. It shall be understood that the gap filling fluid can be described as a viscous material, i.e., a viscous phase that is deposited on the substrate. The gap filling fluid is capable of flowing in a trench on the substrate. Suitable substrates include silicon wafers. As a result, the viscous material seamlessly fills the trench in a bottom-up way.

Flowable films may be temporarily obtained when a volatile precursor is polymerized or oligomerized by a plasma and deposited on a surface of a substrate, wherein gaseous precursor (e.g., monomer) is activated or fragmented by energy provided by plasma gas discharge so as to initiate polymerization/oligomerization, and when the resultant material is deposited on the surface of the substrate, the material shows temporarily flowable behavior. In accordance with exemplary embodiments, when the deposition step is complete, the flowable film is no longer flowable but is solidified, and thus, a separate solidification process is not required. In other embodiments, the flowable film is densified and/or solidified after deposition. Densifying and/or solidifying the flowable film can be done by means of a curing step (also called “cure”).

In some embodiments, the gap filling fluid comprises a polysilazane oligomer. The polysilazane oligomer may be branched or linear. Suitably, the polysilazane oligomer comprises a plurality of oligomeric species, i.e., the gap filling fluid may comprise various different oligomers, both branched and linear.

In some embodiments, the precursor does not contain any carbon, halogens, or chalcogens. In some embodiments, the precursor does not contain any carbon or chalcogens. In some embodiments, the precursor does not contain any carbon. In some embodiments, the precursor does not contain any chalcogens. For example, in some embodiments, the precursor does not contain any carbon, chlorine, or oxygen.

In some embodiments, the co-reactant comprises nitrogen, hydrogen, ammonia, hydrazine, one or more noble gasses, and mixtures thereof. In some embodiments, the co-reactant comprises nitrogen and/or ammonia. In some embodiments, the co-reactant comprises a noble gas. In some embodiments, the noble gas is selected from the list consisting of He, Ne, Ar, and Kr. In some embodiments, the noble gas is Ar.

In some embodiments, all gases supplied to the reaction space throughout the present methods for filling a gap are the precursor, the co-reactant, an optional carrier such as N₂, Ar, and/or He, and an optional plasma ignition gas which can be or include Ar, He, N₂, and/or H₂. In other words, no other gasses are provided to the reaction chamber than those listed, in these embodiments. In some embodiments, the carrier gas and/or the plasma ignition gas functions as a co-reactant.

In some embodiments, the precursor consists of silicon, nitrogen, and hydrogen.

In some embodiments, the precursor can be represented by a chemical formula according to formula (a):

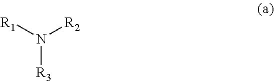

In some embodiments, R₁, R₂, and R₃ are independently selected from SiH₃, SiH₂X, SiHXY, SiX₂Y, and SiX₃ Also, X is a first halogen, and Y is a second halogen. In some embodiments, the first halogen and/or the second halogen are selected from the list consisting of fluorine, chlorine, bromine, and iodine. In some embodiments, the first halogen and/or the second halogen is fluorine. In some embodiments, the first halogen and/or the second halogen is chlorine. In some embodiments, the first halogen and/or the second halogen is bromine. In some embodiments, the first halogen and/or the second halogen is iodine. In some embodiments, at least one of R₁, R₂, and R₃ is SiH₃. In some embodiments, the precursor comprises trisilylamine. When trisilylamine is used as a precursor, the co-reactant may be suitably selected from the list consisting of N₂, NH₃, Ar, and He.

In some embodiments, the precursor can be represented by a chemical formula according to formula (b):

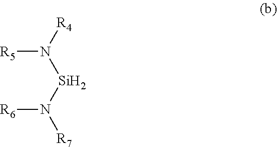

In some embodiments, R₄, R₅, R₆, and R₇ are independently selected from H, SiH₃, SiH₂X, SiHXY, SiX₂Y, and SiX₃. In some embodiments, each of R₄, R₅, R₆, and R₇ comprises SiH₃. In some embodiments, each of R₄, R₅, R₆, and R₇ comprises substantially no Cl, I, or O—C bonds. Also, X is a first halogen, and Y is a second halogen. In some embodiments, the first halogen and/or the second halogen are selected from the list consisting of fluorine, chlorine, bromine, and iodine. In some embodiments, the first halogen and/or the second halogen is fluorine. In some embodiments, the first halogen and/or the second halogen is chlorine. In some embodiments, the first halogen and/or the second halogen is bromine. In some embodiments, the first halogen and/or the second halogen is iodine. In some embodiments, at least one of R₄, R₅, R₆, and R₇ is SiH₃.

In some embodiments, the precursor can be represented by a chemical formula according to formula (c):

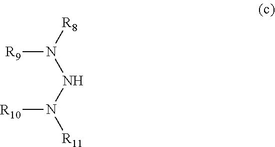

In some embodiments, R₈, R₉, R₁₀, and R₁₁ are independently selected from SiH₃, SiH₂X, SiHXY, SiX₂Y, and SiX₃. Also, X is a first halogen, and Y is a second halogen. In some embodiments, the first halogen and/or the second halogen are selected from the list consisting of fluorine, chlorine, bromine, and iodine. In some embodiments, the first halogen and/or the second halogen is fluorine. In some embodiments, the first halogen and/or the second halogen is chlorine. In some embodiments, the first halogen and/or the second halogen is bromine. In some embodiments, the first halogen and/or the second halogen is iodine. In some embodiments, at least one of R₈, R₉, R₁₀, and R₁₁ is SiH₃.

In some embodiments, the precursor is a hydrosilazane. In some embodiments, the precursor is a cyclohydrosilazane. In some embodiments, the precursor can be represented by a chemical formula according to formula (d):

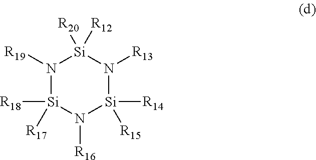

In some embodiments, R₁₂, R₁₃, R₁₄, R₁₅, R₁₆, R₁₇, R₁₈, R₁₉, and R₂₀ are independently selected from the list consisting of H, X, Y, NH₂, SiH₃, SiH₂X, SiHXY, SiX₂Y, and SiX₃. X is a first halogen, and Y is a second halogen. In some embodiments, the first halogen and/or the second halogen are selected from the list consisting of fluorine, chlorine, bromine, and iodine. In some embodiments, the first halogen and/or the second halogen is fluorine. In some embodiments, the first halogen and/or the second halogen is chlorine. In some embodiments, the first halogen and/or the second halogen is bromine. In some embodiments, the first halogen and/or the second halogen is iodine. In some embodiments, at least one of R₁₂, R₁₃, R₁₄, R₁₅, R₁₆, R₁₇, R₁₈, R₁₉, and R₂₀ is H.

In some embodiments, the precursor can be represented by a chemical formula according to formula (e):

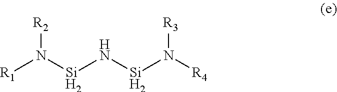

In some embodiments, R₁, R₂, R₃, and R₄ are independently selected from SiH₃, SiH₂X, SiHXY, SiX₂Y, and SiX₃. In some embodiments, X is a first halogen and Y is a second halogen. In some embodiments, the first halogen and/or the second halogen are selected from the list consisting of fluorine, chlorine, bromine, and iodine. In some embodiments, the first halogen and/or the second halogen is fluorine. In some embodiments, the first halogen and/or the second halogen is chlorine. In some embodiments, the first halogen and/or the second halogen is bromine. In some embodiments, the first halogen and/or the second halogen is iodine. In some embodiments, R₁, R₂, R₃, and R₄ are each SiH₃. Thus, in some embodiments, the precursor can be represented by a chemical formula according to formula (f):

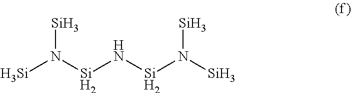

In some embodiments, the precursor comprises a cyclosilazane. Gapfill layers using cyclosilazane precursors provide layers with particularly good lateral flowability, i.e., particularly good flowability in lateral spaces. Suitably, the cyclosilazane only comprises silicon, nitrogen, hydrogen, and optionally a halogen such as chlorine.

In some embodiments, the cyclosilazane comprises a ring structure selected from the group consisting of a cyclotrisilazane ring, a cyclotetrasilazane ring, and a cyclopentasilazane ring.

The gap filling fluids that are deposited herein comprise hydrogen. In some embodiments, the gap filling fluids that are deposited herein comprise from at least 3% to at most 30% H, or from at least 5% to at most 20% H, or from at least 10% to at most 15% H, wherein all percentages are given in atomic percent. Hence, when, for example, a gap filling fluid is referred to as SiN, the breath of the term “SiN” is intended to encompass SiN:H, i.e., SiN comprising hydrogen, e.g., up to 30 atomic percent hydrogen.

In some embodiments, the co-reactant is a carrier gas. It shall be understood that a carrier gas refers to a gas that carries, or entrains, a precursor to the reaction chamber. An exemplary carrier gas includes a noble gas such as argon. Exemplary carrier gas flow rates are of at least 0.1 slm to at most 10 slm, or of at least 0.1 slm to at most 0.2 slm, or of at least 0.2 slm to at most 0.5 slm, or of at least 0.5 slm to at most 1.0 slm, or of at least 1.0 slm to at most 2.0 slm, or of at least 2.0 slm to at most 5.0 slm, or of at least 5.0 slm to at most 10.0 slm, or of at least 0.1 slm to at most 2 slm.

In some embodiments, a volatile precursor is polymerized within a certain parameter range mainly defined by partial pressure of precursor during a plasma strike, wafer temperature, and total pressure in the reaction chamber. In order to adjust the “precursor partial pressure”, an indirect process knob (dilution gas flow) may be used to control the precursor partial pressure. The absolute number of precursor partial pressure may not be required in order to control flowability of deposited film, and instead, a ratio of flow rate of precursor to flow rate of the remaining gas and the total pressure in the reaction space at a reference temperature and total pressure can be used as practical control parameters. The above notwithstanding, and in some embodiments, the reactor chamber is maintained at a pressure of at least 600 Pa to at most 10000 Pa. For example, the pressure in the reaction chamber may be maintained at a pressure of at least 600 Pa to at most 1200 Pa, or at a pressure of at least 1200 Pa to at most 2500 Pa, or at a pressure of at least 2500 Pa to at most 5000 Pa, or at a pressure of at least 5000 Pa to at most 10000 Pa.

In some embodiments, the present methods are executed at a temperature of at least −25 C ° C. to at most 200° C. In some embodiments, the present methods are executed at a temperature of at least −25° C. to at most 0° C. In some embodiments, the present methods are executed at a temperature of at least 0° C. to at most 25° C. In some embodiments, the present methods are executed at a temperature of at least 25° C. to at most 50° C. In some embodiments, the present methods are executed at a temperature of at least 50° C. to at most 75° C. In some embodiments, the present methods are executed at a temperature of at least 75° C. to at most 150° C. In some embodiments, the present methods are executed at a temperature of at least 150° C. to at most 200° C. This enhances the gap filling properties of the presently provided gap filling fluids. In some embodiments, the reactor chamber is at a temperature of at least 70° C. to at most 90° C.

In some embodiments, the present methods are executed at a pressure of at least 500 Pa, preferably at a pressure of at least 700 Pa. More preferably, the present methods are executed at a pressure of at least 900 Pa. This enhances the gap filling properties of the presently provided gap filling fluids.

In some embodiments, the reactor chamber is maintained at a pressure of at least 500 Pa to at most 1500 Pa, and the reactor chamber is maintained at a temperature of at least 50° C. to at most 150° C. In some embodiments, the present methods are executed at a pressure of at least 500 Pa to at most 10 000 Pa and at a temperature of at least 50° C. to at most 200° C. In some embodiments, the present methods are executed at a pressure of at least 700 Pa and at a temperature of at least 50° C. to at most 150° C. In some embodiments, the present methods are executed at a pressure of at least 900 Pa, and at a temperature of at least 50° C. to at most 75° C.

In some embodiments, the methods are executed using a system comprising a precursor source which comprises a precursor recipient, e.g., a precursor canister, a precursor bottle, or the like; and one or more gas lines operationally connecting the precursor recipient to the reaction chamber. In such embodiments, the precursor recipient may be suitably maintained at a temperature which is from at least 5° C. to at most 50° C. lower than the temperature of the reaction chamber, or at a temperature which is from at least 5° C. to at most 10° C. lower than the temperature of the reaction chamber, or at a temperature which is from at least 10° C. to at most 20° C. lower than the temperature of the reaction chamber, or at a temperature which is from at least 30° C. to at most 40° C. lower than the temperature of the reaction chamber, or at a temperature which is from at least 40° C. to at most 50° C. lower than the temperature of the reaction chamber. The gas lines may be suitably maintained at a temperature between the temperature of the precursor recipient and the reaction chamber. For example, the gas lines may be maintained at a temperature which is from at least 5° C. to at most 50° C., or from at least 5° C. to at most 10° C., or from at least 10° C. to at most 20° C., or from at least 30° C. to at most 40° C., or from at least 40° C. to at most 50° C. lower than the temperature of the reaction chamber. In some embodiments, the gas lines and the reaction chamber are maintained at a substantially identical temperature which is higher than the temperature of the precursor recipient.

In some embodiments, the plasma is an RF plasma. In some embodiments, a plasma power of at least 10 W to at most 300 W is used for forming the gap filling fluid. In some embodiments, a plasma power of at least 20 W to at most 150 W is used for forming the gap filling fluid. In some embodiments, a plasma power of at least 30 W to at most 100 W is used for forming the gap filling fluid. In some embodiments, a plasma power of at least 35 W to at most 75 W is used for forming the gap filling fluid. In some embodiments, a plasma power of at least 40 W to at most 50 W is used for forming the gap filling fluid.

In some embodiments, an electrode gap of at least 5 mm to at most 30 mm, e.g., an electrode gap of at least 5 mm to at most 10 mm, or an electrode gap of at least 10 mm to at most 20 mm, or an electrode gap of at least 20 mm to at most 30 mm when the plasma is ignited in the reaction chamber.

In some embodiments, a plasma frequency of at least 40 kHz to at most 2.45 Ghz is used when the plasma is ignited in the reaction chamber, or a plasma frequency of at least 40 kHz to at most 80 kHz is used when the plasma is ignited in the reaction chamber, or a plasma frequency of at least 80 kHz to at most 160 kHz is used when the plasma is ignited in the reaction chamber, or a plasma frequency of at least 160 kHz to at most 320 kHz is used when the plasma is ignited in the reaction chamber, or a plasma frequency of at least 320 kHz to at most 640 kHz is used when the plasma is ignited in the reaction chamber, or a plasma frequency of at least 640 kHz to at most 1280 kHz is used when the plasma is ignited in the reaction chamber, or a plasma frequency of at least 1280 kHz to at most 2500 kHz is used when the plasma is ignited in the reaction chamber, or a plasma frequency of at least 2.5 MHz to at least 5 MHz is used when the plasma is ignited in the reaction chamber, or a plasma frequency of at least 5 MHz to at most 50 MHz is used when the plasma is ignited in the reaction chamber, or a plasma frequency of at least 5 MHz to at most 10 MHz is used when the plasma is ignited in the reaction chamber, or a plasma frequency of at least 10 MHz to at most 20 MHz is used when the plasma is ignited in the reaction chamber, or a plasma frequency of at least 20 MHz to at most 30 MHz is used when the plasma is ignited in the reaction chamber, or a plasma frequency of at least 30 MHz to at most 40 MHz is used when the plasma is ignited in the reaction chamber, or a plasma frequency of at least 40 MHz to at most 50 MHz is used when the plasma is ignited in the reaction chamber, or a plasma frequency of at least 50 MHz to at most 100 MHz is used when the plasma is ignited in the reaction chamber, or a plasma frequency of at least 100 MHz to at most 200 MHz is used when the plasma is ignited in the reaction chamber, or a plasma frequency of at least 200 MHz to at most 500 MHz is used when the plasma is ignited in the reaction chamber, or a plasma frequency of at least 500 MHz to at most 1000 MHz is used when the plasma is ignited in the reaction chamber, or a plasma frequency of at least 1 GHz to at most 2.45 GHz is used when the plasma is ignited in the reaction chamber. In exemplary embodiments, the plasma is an RF plasma, and RF power is provided at a frequency of 13.56 MHz.

In some embodiments, introducing the precursor and the co-reactant occurs simultaneously.

In some embodiments, the co-reactant is provided continuously, the precursor is provided in a plurality of precursor pulses, the plasma is provided in a plurality of plasma pulses, and individual precursor pulses and individual plasma pulses are separated by purge steps.

In some embodiments, the co-reactant comprises nitrogen and ammonia, and no gasses other than the precursor and the co-reactant are introduced into the reactor chamber during the steps of introducing the precursor, the co-reactant, and the plasma into the reaction chamber.

In some embodiments, the co-reactant comprises a noble gas such as He or Ar, and no gasses other than the precursor and the co-reactant are introduced into the reactor chamber during the steps of introducing the precursor, the co-reactant, and the plasma into the reaction chamber.

In some embodiments, present methods include exposing the gap filling fluid to a radio frequency (RF) plasma and make used of a cyclic deposition process employing pulsed precursor flow and a pulsed RF plasma. The precursor pulses and the plasma pulses may be separated by purge gas pulses. In some embodiments, the duration of the purge steps and the flow rate of purge gas is selected to be sufficiently low as to ensure that not all precursor has been removed from the reaction chamber after the purge step has finished. In other words, the duration of the purge steps and purge gas flow rates used therein can be sufficiently low such that the entire reaction chamber is not evacuated during a purge step. Preferably, the co-reactant is used as a purge gas. In such embodiments, the desired aspects for flowability of depositing film include: 1) high enough partial pressure during the entire RF-on period for polymerization to progress; 2) sufficient energy to activate the reaction (defined by the RF-on period and RF power), during an RF period which is not too long; 3) Temperature and pressure for polymerization/chain growth set above the melting point and below the boiling point of the flowable phase; 4) temperature and pressure for polymerization chain growth selected at sufficiently low levels such that the gap filling fluid has sufficient time to fill the gap before it solidifies, e.g., due to chain growth.

In some embodiments, the present methods involve providing the precursor intermittently to the reaction space, and continuously applying a plasma. In some embodiments, the present methods involve providing the precursor intermittently to the reaction space, and intermittently applying a plasma. The latter embodiments thus feature the sequential application of precursor pulses and plasma pulses to the reaction space. Preferably, the precursor pulses and the plasma pulses are separated by purge gas pulses.

In some embodiments, the present methods involve providing the precursor continuously to the reaction space, and continuously or cyclically applying a plasma, e.g., through application of RF power, throughout the deposition step. The plasma may be continuous or pulsed, and it may be direct or remote.

In some embodiments, the present methods involve providing the precursor continuously to the reaction chamber, continuously providing the co-reactant to the reaction chamber, and continuously providing a plasma in the reaction chamber.

In a preferred mode of operation, the flowable film is deposited by employing alternating precursor and plasma pulses.

In some embodiments, a pulsed plasma, e.g., a pulsed RF plasma is applied. In some embodiments, the period of RF power application (i.e., the period in which reactants in the reactor are exposed to plasma) is in the range of at least 0.7 seconds to at most 2.0 seconds, for example from at least 0.7 seconds to at most 1.5 seconds.

In some embodiments, the plasma exposure time is adjusted by changing the distance between upper and lower electrodes. Indeed, by increasing this distance, the retention time by which the precursor is retained in the reaction space between upper and lower electrodes is prolonged when the flow rate of precursor entering into the reaction space is kept constant. In some embodiments, the distance between the upper and lower electrodes is from at least 5.0 mm to at most mm, or from at least 10.0 mm to at most 25.0 mm, or from at least 15.0 mm to at most 20.0 mm.

In some embodiments, the plasma is an RF plasma. In some embodiments, RF power is provided at a frequency of 13.56 MHz. In some embodiments, the RF power provided for flowable film deposition is from at least 50 W to at most 1000 W, or from at least 100 W to at most 900 W, or from at least 200 W to at most 800 W, or from at least 300 W to at most 700 W, or from at least 400 W to at most 600 W, or from at least 500 W to at most 550 W. It shall be understood that these powers are provided for the special case of 300 mm wafers. They can be readily converted to units of W/cm² to obtain equivalent RF power values for different wafer sizes.

In some embodiments, the present methods involve providing the precursor in a pulse and involve providing the RF power in a further pulse, wherein the two pulses do not overlap. The precursor pulses and the plasma pulses may be separated by purge gas pulses. Thus, in some embodiments, the method for filling a gap comprises a plurality of deposition cycles comprising alternating pulses in which precursor is provided, and pulses in which RF power is provided for generating a plasma. In other words, in some embodiments, the method for filling a gap comprises a plurality of deposition cycles, a deposition cycle comprises a pulse in which precursor is provided, and a pulse in which RF power is provided for generating a plasma. Preferably, these precursor pulses and plasma pulses are separated by purge pulses in which a purge gas is flowed. In the following paragraphs, process conditions are given for a reactor chamber volume of 1 liter and for 300 mm wafers. The skilled person understands that these values can be readily extended to other reactor chamber volumes and wafer sizes.

In some embodiments, the method for filling a gap comprises from at least 10 to at most 30000 deposition cycles, or from at least 10 to at most 3000 deposition cycles, or from at least 10 to at most 1000 deposition cycles, or from at least 10 to at most 500 deposition cycles, or from at least 20 to at most 200 deposition cycles, or from at least 50 to at most 150 deposition cycles, or from at least 75 to at most 125 deposition cycles, for example 100 deposition cycles.

In some embodiments, the co-reactant is supplied to the reactor chamber as a carrier gas, i.e., as a gas that entrains the precursor, and/or as an additional gas. In some embodiments, the carrier gas is provided at a flow rate of at least 0.2 to at most 2.0 slpm, or from at least 0.3 to at most 1.5 slpm, or from at least 0.4 to at most 1.0 slpm, or from at least 0.5 to at most 0.7 slpm.

In some embodiments, the deposition cycles comprise a sequence of a precursor pulse, a precursor purge, a plasma pulse, and a post plasma purge, which are continually repeated.

In some embodiments, the duration of the precursor pulse, i.e., the precursor feed time, is from at least 0.25 s to at most 4.0 s, or from at least 0.5 s to at most 2.0 s, or from at least 1.0 s to at most 1.5 s.

In some embodiments, the duration of the purge step directly after the precursor pulse, i.e., the precursor purge time, is from at least 0.025 s to at most 2.0 s, or from at least 0.05 s to at most 0.8 s, or from at least 0.1 s to at most 0.4 s, or from at least 0.2 s to at most 0.3 s. This timing applies both for the case when N₂ and/or NH₃ is used as a co-reactant, and when a noble gas such as Ar is used as a co-reactant.

In some embodiments, the RF on time, i.e., the duration of a plasma pulse, that is the time during which RF power is provided during a plasma pulse, is from at least 0.5 s to at most 4.0 s, or from at least 0.7 s to at most 3.0 s, or from at least 1.0 s to at most 2.0 s, or from at least 1.25 s to at most 1.75 s, or of about 1.5 s. When N₂ and/or NH₃ is used as a co-reactant, the duration of a plasma pulse is preferably from at least 0.75 to at most 3.0 s, or from at least 1.0 to at most 2.0 s.

In some embodiments, the post plasma purge time, i.e., the duration of the purge which occurs after application of a plasma pulse, is from at least 0.1 s to at most 2.0 s, or from at least 0.1 to at most 1.5 s for example 1.0 s.

In some embodiments, the substrate rests on a susceptor in the reactor chamber during the deposition cycles, and the susceptor temperature is from at least 50° C. to at most 100° C., or from at least 60° C. to at most 80° C., or from at least 65° C. to at most 75° C.

The presently provided gap filling fluids can, in some embodiments, spontaneously solidify after deposition through recombination. Therefore, a separate curing step may not be necessary. Nevertheless, a curing step, e.g., a plasma curing step can be advantageous in order to improve one or more advantageous film properties such as resistance to shrinkage at high temperature and a low wet etch rate. The term “curing” can refer to a process of cross linking of as-deposited gap filling fluid oligomers, e.g., by means of a plasma such as a direct plasma or a remote plasma.

Suitable plasma treatments include a H₂ plasma, a He plasma, a H₂/He plasma, an Ar plasma, an Ar/H₂ plasma, and an Ar/He/H₂ plasma. It shall be understood that a H₂ plasma refers to a plasma that employs H₂ as a plasma gas. Also, it shall be understood that a H₂/He plasma refers to a plasma that employs a mixture of H₂ and He as a plasma gas. It shall be understood that other plasmas are defined analogously.

Accordingly, in some embodiments, the method includes a step of curing the gap filling fluid. This step increases the thermal resistance of the gap filling fluid. In other words, it increases the resistance of the gap filling fluid against deformation and/or mass loss at elevated temperatures. Additionally, or alternatively, the curing step may cause the gap filling fluid to solidify.

In some embodiments, the gap filling fluid is cured after it has been deposited. Additionally, or alternatively, the gap filling fluid may be cured during deposition, e.g., by cyclically alternating deposition pulses and curing pulses.

In some embodiments, the step of curing involves exposing the gap filling fluid to a cyclic plasma treatment. When a cyclic plasma treatment is performed, deposition cycles and plasma curing cycles are alternated. The term “plasma curing cycle” refers to a plasma treatment step in which gap filling fluid is cured. In some embodiments, the cyclic plasma treatment involves the use of a gas mixture that does not comprise nitrogen.

A step of curing the gap filling fluid may involve, for example, exposing the gap filling fluid to a direct plasma. When a direct plasma is used, a thin layer of gap filling fluid may be efficiently cured, yielding a thin high-quality layer. In some embodiments, especially when a thicker layer of cured gap filling fluid is desired, the method for filling a gap may comprise a plurality of cycles in which gap filling fluid deposition steps and curing steps employing a direct plasma treatment are alternated.

Thus, in some embodiments, the cyclic plasma treatment, employs a direct plasma. In such embodiments, the process of filling a gap preferably comprises a plurality of cycles, i.e., plasma curing cycles, and gap filling fluid deposition and plasma treatment steps are alternated. Such a cyclic process has the advantage that a larger portion of the gap filling fluid is cured: a direct plasma can have a penetration depth of around 2 to 7 nm, such that a post deposition direct plasma treatment would only cure a top layer of the gap filling fluid. Conversely, alternating deposition and plasma steps allows curing a larger part, or even the entirety of the gap filling fluid, even when using a curing technique which has a low penetration depth, such as a direct plasma.

Optionally, the gap filling fluid is subjected to an anneal after the gap filling fluid has been deposited and before the curing step. Suitable annealing times include from at least 10.0 seconds to at most 10.0 minutes, for example from at least 20.0 seconds to at most 5.0 minutes, for example from at least 40.0 seconds to at most 2.5 minutes. Suitably, the anneal is performed in a gas mixture comprising one or more gasses selected from the list consisting of N₂, He, Ar, and H₂. Preferably, the anneal is carried out in an atmosphere that comprises N₂. In some embodiments, the anneal is carried out at a temperature of at least 200° C., or at a temperature of at least 250° C., or at a temperature of at least 300° C., or at a temperature of at least 350° C., or at a temperature of at least 400° C., or at a temperature of at least 450° C.

In some embodiments, the step of curing involves the use of an indirect plasma after the gap has been filled with the gap filling fluid. An indirect plasma can have a larger penetration depth than a direct plasma, thereby obviating the need for cyclic deposition and curing steps. Thus, an indirect plasma cure may be applied post deposition.

The step of curing may involve exposing the gap filling fluid to a noble gas plasma. In some embodiments, the noble gas plasma is a direct plasma. In some embodiments, the noble gas plasma is a remote plasma.

The step of curing may reduce the hydrogen concentration of the gap filling fluids. For example, the hydrogen concentration is reduced by at least 0.01 atomic percent to at most 0.1 atomic percent, or by at least 0.1 atomic percent to at most 0.2 atomic percent, or by at least 0.2 atomic percent to at most 0.5 atomic percent, or by at least 0.5 atomic percent to at most 1.0 atomic percent, or by at least 1.0 atomic percent to at most 2.0 atomic percent, or by at least 2.0 atomic percent to at most 5.0 atomic percent, or by at least 5.0 atomic percent to at most 10.0 atomic percent.

In some embodiments, the step of curing involves exposing the gap filling fluid to a remote plasma. The radicals produced by remote plasmas feature a penetration depth which is significantly higher than the penetration length offered by direct plasmas, e.g., significantly higher than the size of the gaps to be filled by means of the presently provided methods. Consequently, a remote plasma treatment may be advantageously applied once after all the gap filling fluid has been deposited. This notwithstanding, a remote plasma cure may also be applied cyclically with alternating plasma cure and gap filling fluid deposition steps, similar to the operation with a direct plasma. The large penetration depths of remote plasmas have the advantage that they allow efficient curing of gap filling fluid. In some embodiments, the plasma gas employed in a remote plasma comprises a noble gas, for example a noble gas selected from the list consisting of He and Ar.

In some embodiments, the cyclic plasma treatment involves the use of a noble gas such as Ar or He as a plasma gas.

In some embodiments, the step of curing involves exposing the gap filling fluid to a micro pulsed plasma. The application of a micro-pulsed plasma can be particularly advantageous when, for example, the as-deposited gap filling fluid comprises hydrogen. A micro pulsed plasma is a plasma treatment that comprises the application of a plurality of rapidly succeeding on-off micro pulses. The micro pulsed plasma may, for example, employ a noble gas as a plasma gas. When a 300 mm wafer is used as a substrate, a plasma gas flow rate of, for example, at least 5.0 slm, or of at least 5.0 slm to at most 7.0 slm, or of at least 7.0 slm to at most 10.0 slm is maintained during the micro pulsed plasma. For example, the on micro pulses in a micro pulsed plasma may last from at least 1.0 μs to at most 1.0 s, or from at least 2.0 μs to at most 0.50 s, or from at least 5.0 μs to at most 250 ms, or from at least 10.0 μs to at most 100.0 ms, or from at least 25.0 μs to at most 50.0 ms, or from at least 50.0 μs to at most 25.0 ms, or from at least 100.0 μs to at most 10.0 ms, or from at least 250.0 μs to at most 5.0 ms, or from at least 0.50 ms to at most 2.5 ms. For example, the off micro pulses in a micro pulsed plasma may last from at least 1.0 μs to at most 2.0 s, or from at least 2.0 μs to at most 1.0 s, or from at least 5.0 μs to at most 500 ms, or from at least 10.0 μs to at most 250.0 ms, or from at least 25.0 μs to at most 100.0 ms, or from at least 50.0 μs to at most 50.0 ms, or from at least 100.0 μs to at most 25.0 ms, or from at least 200.0 μs to at most 10.0 ms, or from at least 500.0 μs to at most 5.0 ms, or from at least 1.0 ms to at most 2.0 ms. A micro pulsed plasma may be used cyclically and/or as a post-deposition treatment. In other words, a process of filling a gap may feature alternating cycles of gap filling fluid deposition and micro pulsed plasma. Additionally, or alternatively, a micro pulsed plasma may be applied as a post-deposition treatment after all gap filling fluid has been deposited.

In some embodiments, a micro pulsed plasma is applied together with a plasma gas flow rate that is higher than a pre-determined threshold. The combination of a micro pulsed plasma with these high flow rates minimizes redeposition of volatile by products released during plasma-induced cross linking of the deposited gap filling fluid. In some embodiments, the flow rate of the plasma gas during micro pulsed plasma treatment is at least 5.0 slm (standard liter per minute), preferably at least 10.0 slm. The skilled artisan understands that this flow rate depends on reactor chamber volume and substrate size, and the values provided here for 300 mm wafers and a reactor chamber volume of 1 liter can be readily transferred to other substrate sizes and/or reactor volumes. In some embodiments, a noble gas is used as a plasma gas during micro pulsed plasma treatment. In some embodiments, the noble gas is selected from the list consisting of He and Ar.

In some embodiments, the step of curing involves the use of ultraviolet (UV) light. In other words, the step of curing may involve exposing the substrate, including the gap filling fluid, to UV radiation. Such a curing step employing UV light may be called a UV cure.

In some embodiments, a UV cure is used as a post-deposition treatment. In other words, in some embodiments, the present methods can comprise depositing a gap filling fluid, and after all gap filling fluid has been deposited, subjecting the gap filling fluid to a UV cure.

In some embodiments, the present methods comprise a cyclic process comprising a plurality of cycles, the cycles each comprising a deposition step and a UV curing step. The UV curing step may be separated by a purge step. Additionally, or alternatively, subsequent cycles may be separated by a purge step. Suitable purge steps are described elsewhere herein.

In some embodiments, the method includes entirely filling the gap with a gap filling fluid. In some embodiments, the method includes filling the gap with gap filling fluid without the formation of voids. In other words, in some embodiments, the deposition according to the present methods is continued until the gap is fully filled with a material having filling capability, and substantially no voids are formed in the filled gap. The presence of voids can be observed by studying the formed material in a scanning tunneling electron microscope.

In some embodiments, the gap has a depth of at least 5 nm to at most 500 nm, or of at least 10 nm to at most 250 nm, or from at least 20 nm to at most 200 nm, or from at least 50 nm to at most 150 nm, or from at least 100 nm to at most 150 nm.

In some embodiments, the gap has a width of at least 10 nm to at most 10 000 nm, or of at least 20 nm to at most 5 000 nm, or from at least 40 nm to at most 2 500 nm, or from at least 80 nm to at most 1000 nm, or from at least 100 nm to at most 500 nm, or from at least 150 nm to at most 400 nm, or from at least 200 nm to at most 300 nm.

In some embodiments, the gap has a length of at least 10 nm to at most 10 000 nm, or of at least 20 nm to at most 5 000 nm, or from at least 40 nm to at most 2 500 nm, or from at least 80 nm to at most 1000 nm, or from at least 100 nm to at most 500 nm, or from at least 150 nm to at most 400 nm, or from at least 200 nm to at most 300 nm.

In some embodiments, the gap filling fluid extends into a particular gap for a distance that equals from at least 1.0 to at most 10.0 times the width of the gap. In some embodiments, the gap filling fluid extends into a particular gap for a distance that equals from at least 1.5 to at most 9.0 times the width of the gap. In some embodiments, the gap filling fluid extends into a particular gap for a distance that equals from at least 2.0 to at most 8.0 times the width of the gap. In some embodiments, the gap filling fluid extends into a particular gap for a distance that equals from at least 3.0 to at most 6.0 times the width of the gap. In some embodiments, the gap filling fluid extends into a particular gap for a distance that equals from at least 4.0 to at most 6.0 times the width of the gap. In some embodiments, the gap filling fluid extends into a particular gap for a distance that equals about 5.0 times the width of the gap.

Further described is a system that is suitable for performing a method as disclosed herein. The system comprises one or more reaction chambers and a gas injection system fluidly coupled to at least one of the one or more reaction chambers. The system further comprises a first gas source for introducing a precursor and optionally a carrier gas in the reactor chamber. Suitable carrier gasses include gasses that may be used as a co-reactant, such as noble gasses, N₂, NH₃, H₂, etc. The system may further comprise a second gas source for introducing a mixture of one or more further gasses into the reactor chamber. The second gas source may be present, for example, when the carrier gas is different from the co-reactant. The system further comprises an exhaust for exhausting reaction products, carrier gas, and unused precursor and co-reactant. Also, the system comprises a controller. The controller is configured to control gas flow into the gas injection system and for causing the system to carry out a method as described herein.

In some embodiments, the gas injection system comprises a precursor delivery system that employs a carrier gas for carrying the precursor to one or more reactor chambers. In some embodiments, continuous flow of carrier gas is accomplished using a flow-pass system, wherein a carrier gas line is provided with a detour line having a precursor reservoir (bottle), and the main line and the detour line are switched, wherein when only a carrier gas is intended to be fed to a reaction chamber, the detour line is closed, whereas when both the carrier gas and the precursor gas are intended to be fed to the reaction chamber, the main line is closed and the carrier gas flows through the detour line and flows out from the bottle together with the precursor gas. In this way, the carrier gas can continuously flow into the reaction chamber and can carry the precursor gas in pulses by switching the main line and the detour line.

The skilled artisan will appreciate that the apparatus includes one or more controller(s) programmed or otherwise configured to cause the deposition process described elsewhere herein to be conducted. The controller(s) communicate with the various power sources, heating systems, pumps, robotics, and gas flow controllers or valves of the reactor, as will be appreciated by the skilled artisan and further described below.

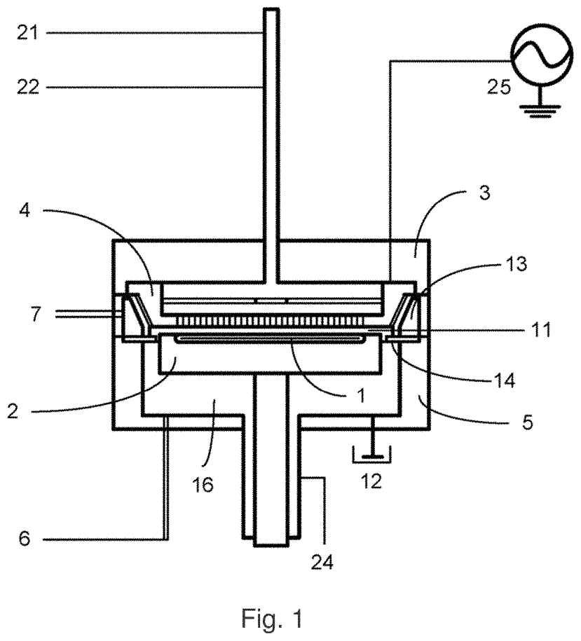

The presently provided methods may be executed in any suitable apparatus, including in a reactor as shown in FIG. 1. Similarly, the presently provided structures may be manufactured in any suitable apparatus, including a reactor as shown in FIG. 1. FIG. 1 is a schematic view of a plasma-enhanced atomic layer deposition (PEALD) apparatus, desirably in conjunction with controls programmed to conduct the sequences described below, usable in some embodiments of the present invention. In this figure, by providing a pair of electrically conductive flat-plate electrodes (2,4) in parallel and facing each other in the interior (11) (reaction zone) of a reaction chamber (3), applying RF power (e.g., at 13.56 MHz and/or 27 MHz) from a power source (25) to one side, and electrically grounding the other side (12), a plasma is excited between the electrodes. A temperature regulator may be provided in a lower stage (2), i.e., the lower electrode. A substrate (1) is placed thereon, and its temperature is kept constant at a given temperature. The upper electrode (4) can serve as a shower plate as well, and a reactant gas and/or a dilution gas, if any, as well as a precursor gas can be introduced into the reaction chamber (3) through a gas line (21) and a gas line (22), respectively, and through the shower plate (4). Additionally, in the reaction chamber (3), a circular duct (13) with an exhaust line (17) is provided, through which the gas in the interior (11) of the reaction chamber (3) is exhausted. Additionally, a transfer chamber (5) is disposed below the reaction chamber (3) and is provided with a gas seal line (24) to introduce seal gas into the interior (11) of the reaction chamber (3) via the interior (16) of the transfer chamber (5) wherein a separation plate (14) for separating the reaction zone and the transfer zone is provided. Note that a gate valve through which a wafer may be transferred into or from the transfer chamber (5) is omitted from this figure. The transfer chamber is also provided with an exhaust line (6). In some embodiments, the deposition of multi-element film and surface treatment are performed in the same reaction space, so that all the steps can continuously be conducted without exposing the substrate to air or other oxygen-containing atmosphere.

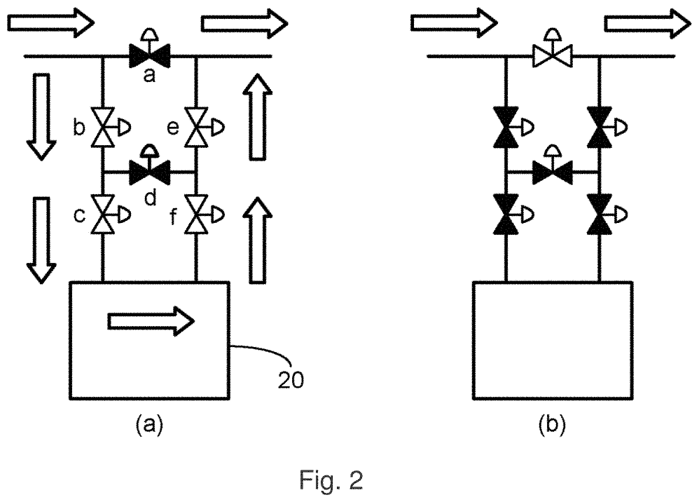

In some embodiments, the apparatus depicted in FIG. 1, the system of switching flow of an inactive gas and flow of a precursor gas illustrated in FIG. 2 can be used to introduce the precursor gas in pulses without substantially fluctuating pressure of the reaction chamber.

Indeed, a continuous flow of the carrier gas can be accomplished using a flow-pass system (FPS) wherein a carrier gas line is provided with a detour line having a precursor reservoir (bottle), and the main line and the detour line are switched, wherein when only a carrier gas is intended to be fed to a reaction chamber, the detour line is closed, whereas when both the carrier gas and a precursor gas are intended to be fed to the reaction chamber, the main line is closed and the carrier gas flows through the detour line and flows out from the bottle together with the precursor gas. In this way, the carrier gas can continuously flow into the reaction chamber and can carry the precursor gas in pulses by switching the main line and the detour line. FIG. 2 illustrates a precursor supply system using a flow-pass system (FPS) according to an embodiment of the present invention (black valves indicate that the valves are closed). As shown in (a) in FIG. 2, when feeding a precursor to a reaction chamber (not shown), first, a carrier gas such as Ar (or He) flows through a gas line with valves b and c, and then enters a bottle (reservoir) (20). The carrier gas flows out from the bottle (20) while carrying a precursor gas in an amount corresponding to a vapor pressure inside the bottle (20) and flows through a gas line with valves f and e and is then fed to the reaction chamber together with the precursor. In the above, valves a and d are closed. When feeding only the carrier gas (which can be a noble gas such as He or Ar) to the reaction chamber, as shown in (b) in FIG. 2, the carrier gas flows through the gas line with the valve a while bypassing the bottle (20). In the above, valves b, c, d, e, and f are closed.

As noted, a skilled artisan will appreciate that the apparatus includes one or more controller(s) (not shown) programmed or otherwise configured to cause the deposition process described elsewhere herein to be conducted. The controller(s) communicate with the various power sources, heating systems, pumps, robotics and gas flow controllers or valves of the reactor, as will be appreciated by the skilled artisan. The controller(s) include electronic circuitry including a processor, and software to selectively operate valves, manifolds, heaters, pumps, and other components included in the system. Such circuitry and components operate to introduce precursors, reactants, and optionally purge gases from the respective sources (e.g., bottle 20). The controller can control timing of gas supply sequences, temperature of the substrate and/or reaction chamber (3), pressure within the reaction chamber (3), and various other operations to provide proper operation of the system. The controller(s) can include control software to electrically or pneumatically control valves to control flow of precursors, reactants, and purge gases into and out of the reaction chamber (3). Controller(s) can include modules such as a software or hardware component, e.g., a FPGA or ASIC, which performs certain tasks. It shall be understood that where the controller includes a software component to perform a certain task, the controller is programmed to perform that particular task. A module can advantageously be configured to reside on the addressable storage medium, i.e., memory, of the control system and be configured to execute one or more processes.

Optionally, a dual chamber reactor can be used. A dual chamber reactor comprises two sections or compartments for processing wafers disposed close to each other. In such a dual chamber reactor, a reactant gas and a noble gas can be supplied through a shared line and precursor-containing gases are provided by means of unshared lines. In exemplary embodiments, forming a gap filling fluid occurs in one of the two compartments, and the step of curing occurs in another reaction chamber. This can advantageously improve throughput, e.g., when gap filling fluid formation and curing occur at different temperatures.

As a further example, an exemplary curing step is discussed. The curing step may employ a continuous direct plasma for 20 seconds. Gap filling fluid deposition steps and direct plasma curing steps may be carried out cyclically, i.e., gap filling fluid deposition steps and curing steps may be executed alternatingly. This allows efficiently curing all, or at least a large portion, of the gap filling fluid. For curing gap filling fluid in gaps on a 300 mm substrate, each direct plasma curing step can feature, for example, 20 seconds of He plasma at an RF power of 200 W and a working pressure of 600 Pa. The reactor volume is ca. 1 liter and the He flow rate is 2 slm.

As a further example, another exemplary curing step is discussed. The curing step may involve exposing the gap filling fluid to a micro pulsed plasma. In the present example, the curing step may be carried out cyclically, i.e., alternating cycles of gap filling fluid deposition and micro pulsed RF plasma are employed, though a post-deposition micro pulsed plasma curing treatment is possible as well. The application of cyclic gap filling fluid deposition and plasma steps allows efficiently curing all, or at least a large portion, of the gap filling fluid. For curing gap filling fluid in gaps on a 300 mm substrate, each direct curing step may feature 200 micro-pulses comprising 0.1 seconds of plasma on time and 0.5 seconds of plasma off time. The curing step may employ a He plasma at 400 Pa. The RF power provided may be 200 W. A He flow of 10 slm may be employed.

The gap filling fluid may comprise a branched polysilazane oligomer comprising a plurality of oligomeric species. In other words, the branched polysilazane oligomer comprises a plurality of different macromolecules that may have a varying morphology.

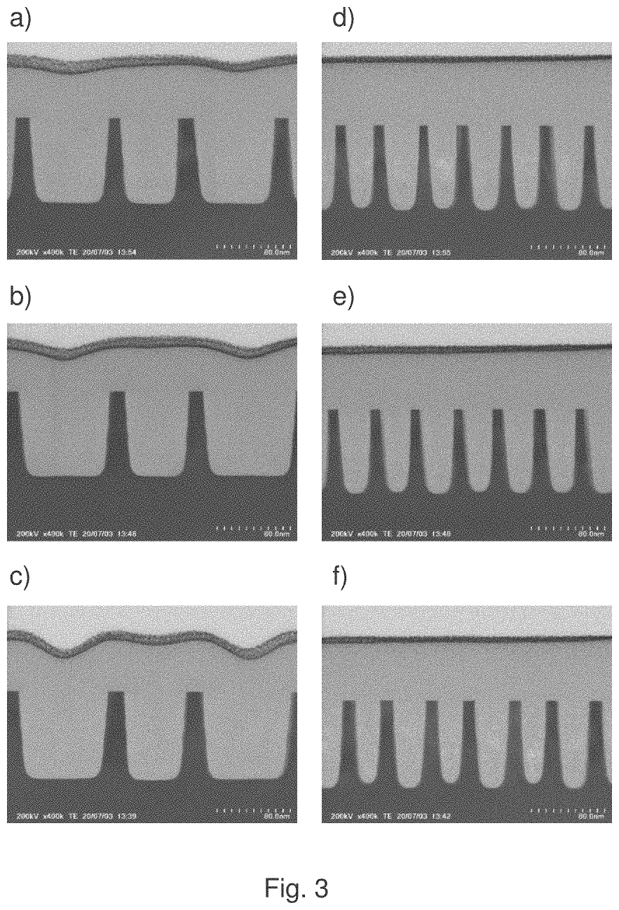

In a further example, reference is made to FIG. 3 which shows experimental results showing excellent filling capability of gap filling fluids deposited by means of an embodiment of a method according to the present disclosure. Panels a) through f) show transmission electron micrographs of gap filling fluids deposited using trisilylamine as a precursor and argon as a plasma gas.

In particular, FIG. 3 panels a) and d) show the results of a process in which an argon carrier gas flow rate of 4.0 slm was used, the reaction chamber was maintained at a pressure of 800 Pa, a plasma power of 28 W was used, an electrode gap of 12 mm was used, plasma on time was 60 seconds, the reaction chamber, and in particular the susceptor on which the substrate rests during the method, was maintained at a temperature of 75° C. A trisilylamine container was used as precursor source, and it was maintained at a temperature of 50° C. Such films offer excellent filling capability.

FIG. 3 panels b) and e) show the results of a process in which an argon carrier gas flow rate of 3.0 slm was used, the reaction chamber was maintained at a pressure of 800 Pa, a plasma power of 28 W was used, an electrode gap of 12 mm was used, plasma on time was 60 seconds, the reaction chamber, and in particular the susceptor on which the substrate rests during the method, was maintained at a temperature of 75° C. A trisilylamine container was used as precursor source, and it was maintained at a temperature of 50° C. Such films offer excellent filling capability.

FIG. 3 panels c) and f) show the results of a process in which an argon carrier gas flow rate of 4.0 slm was used, the reaction chamber was maintained at a pressure of 800 Pa, a plasma power of 25 W was used, an electrode gap of 12 mm was used, plasma on time was 60 seconds, the reaction chamber, and in particular the susceptor on which the substrate rests during the method, was maintained at a temperature of 75° C. A trisilylamine container was used as precursor source, and it was maintained at a temperature of 50° C. Such films offer excellent filling capability.

In a further example, the precursor according to formula (b), wherein each of R₄, R₅, R₆, and R₇ comprises SiH₃, was utilized in a chemical vapor deposition (CVD) of flowable gap-fill fluid under the conditions listed in Table 1:

TABLE 1

| Vapor Pressure | 20 Torr at 25° C. | |
|---|---|---|
| Ar Source Temperature | 22° | C. |
| Reaction Chamber Wall Temperature | 65° | C. |
| Showerhead Injector Temperature | 70° | C. |
| Susceptor Temperature | 75° | C. |
| Ar Flow Rate | 4 | SLM |
| Reaction Chamber Pressure | 600-1100 | Pa |
| High Radio Frequency Power | 50-150 | W |
| Gap | 10-15 | mm |
| Ignition Step | 5 | s |

| | |
|---|---|
| Feed | Continuous |
| RF | Continuous |

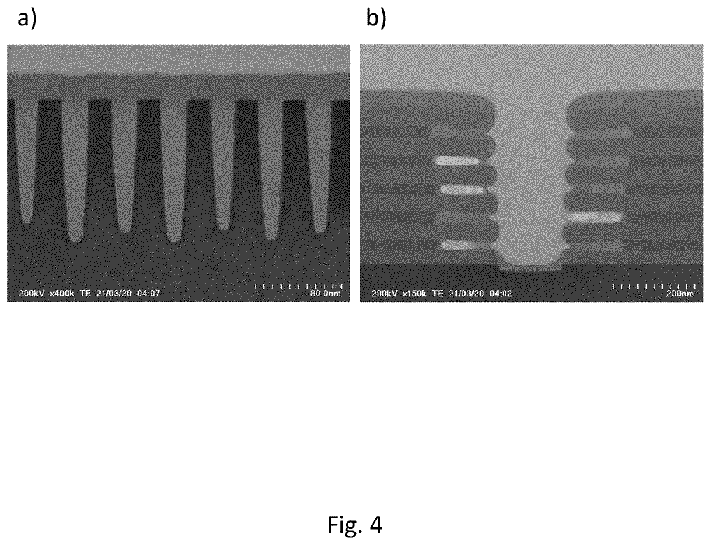

FIG. 4 illustrates transmission electron micrographs of gaps filled with gap filling fluids deposited according to the embodiment under the conditions of Table 1. As illustrated, in some embodiments, high flowability with lateral filling capability may be achieved by the methods described herein.

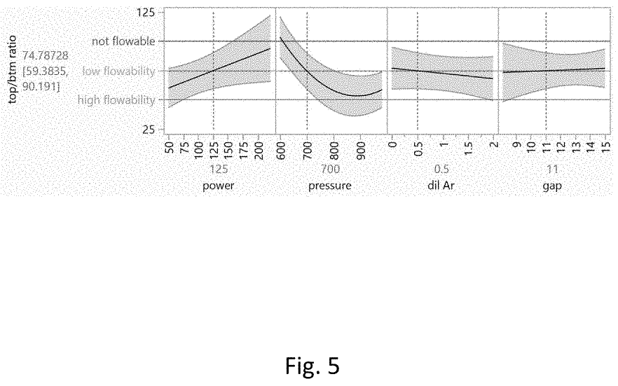

FIG. 5 illustrates an example film flowability model/window for a flowable gap fill film according to some embodiments. As shown in FIG. 5, in some embodiments, power and pressure are the most significant parameters for flowability of the film. However, it will be understand by those skilled in the art that various parameters may be adjusted to increase or decrease film flowability, including temperature, gas flow rates, and pressure.

The film properties of a deposited film according to the deposition of flowable gap-fill fluid under the conditions listed in Table 1 and using the precursor according to formula (b) are listed in Table 2, wherein WERR is the wet etch rate in 0.5 vol. % HF in H₂O, NU is the thickness non-uniformity over a wafer surface, 1 sig is one standard deviation from the mean value, RI is the refractive index, AR fill capability is the maximum aspect ratio (depth/width) that may be completely filled by the gap fill fluid:

TABLE 2

| Vapor Pressure | 20 Torr at 25° C. | |
|---|---|---|
| Stoichiometry (Si/N/H) | (5/2/14) | |
| Deposition Rate | 58 | nm/min |
| Aging | Severe Oxidation | |
| | without cap | |
| WERR | >82 | |
| NU | 4.8% | [1 sig] |
| Shrinkage at 400° C. for 30 | 11% | |
| min 100 Pa N₂ | | |
| RI | 1.59 | |
| Density | 1.29 | g/cm³ |
| Stress | −9 | MPa |

| | |
|---|---|
| Particles | OL |
| AR Fill Capability | 5 |

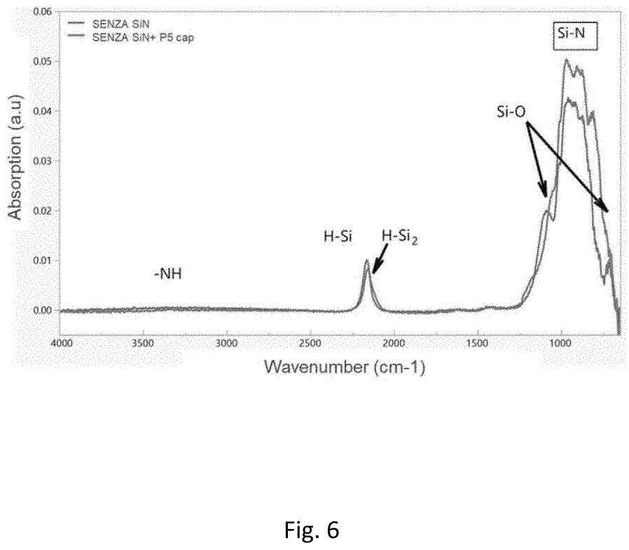

A compositional analysis by Elastic Recoil Detection (ERD) showed an oxygen content of about 2.3% after 2 days and about 2.9% after 5 days for a capped sample, and an oxygen content of about 4% after 2 days and about 27.6% after 5 days for an uncapped sample. In some embodiments, including in generating the samples of Table 2, the cap comprises silicon nitride formed using Plasma Enhanced Chemical Vapor Deposition (PECVD), including a plasma, wherein the plasma gas comprises a SiH₄ precursor and a NH₃ reactant. FIG. 6 illustrates a composition analysis performed by Fourier Transformed Infrared Spectroscopy (FTIR) of the capped and uncapped sample. The FTIR analysis shows the SiN film signature, as well as a clear SiO peak for the uncapped sample.

As described above, in some embodiments, the step of curing involves exposing the gap filling fluid to a cyclic plasma treatment. Table 3 shows the properties a film formed according to the embodiments herein both with and without a cyclic plasma treatment, with RI and WERR measured after an anneal for 30 min at 400° C. in N₂:

TABLE 3

| Item | Untreated | Treated |
|---|---|---|
| RI | 1.59 | 2.23 |
| WERR | >82 | 4.9 |
| Shrinkage | 11 | 0 |
| RI After Anneal | 1.41 | 2.37 |
| WERR After Anneal | 18.7 | 4.0 |

As shown in Table 3, a cyclic plasma treatment may greatly improve WERR and shrinkage. The cyclic plasma treatment used to generate the results of Table 3 comprised using a direct plasma comprising a mixture of helium and H₂ as a plasma gas on every 5 nm of film at 300 W, 500 Pa, and for 15 seconds. A composition analysis of the treated and untreated films can be found in Table 4:

TABLE 4

| | | | | |
|---|---|---|---|---|
| Item | Si2p | C1s | N1s | O1s |

| | | | | | |
|---|---|---|---|---|---|
| Untreated | Uncapped | 50 | 4 | 18 | 27 |
| | Capped | 53 | 0 | 44 | 3 |
| Treated | Uncapped | 58 | 0 | 29 | 13 |
| | Capped | 61 | 0 | 36 | 3 |

As shown in Table 4, the cyclic plasma treatment reduced the oxygen content in the film, especially for the uncapped sample. In some embodiments, capping the sample may reduce oxygen intake of the film further.

In a further example, the precursor according to formula (f), was utilized in a chemical vapor deposition (CVD) of flowable gap-fill fluid at a vapor pressure of 2 Torr at 25° C. and a stoichiometry (Si/N/H) of 6/3/17. Table 5 shows the resulting as-deposited and treated film properties:

TABLE 5

| As-Deposited Film | Deposition Rate | 67 | nm/min |
|---|---|---|---|
| | WERR | 63 | |
| | NU | >50% | [1 sig] |

| | | |
|---|---|---|
| | Shrinkage at 400° C. for 30 | 21% |
| | min 100 Pa N₂ | |
| | RI | 1.616 |
| | Particles | OL |
| | AR Filling Capability | 3-6 |
| Treated Film | WERR | 1-5 |
| | Shrinkage at 400° C. for 30 | −1-3% |
| | min 100 Pa N₂ | |
| | RI | −2.4 |
| | AR Filling Capability | <1.3 |

Although certain embodiments and examples have been discussed, it will be understood by those skilled in the art that the scope of the claims extend beyond the specifically disclosed embodiments to other alternative embodiments and/or uses and obvious modifications and equivalents thereof. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

In the present disclosure, where conditions and/or structures are not specified, the skilled artisan in the art can readily provide such conditions and/or structures in view of the present disclosure, as a matter of routine experimentation.

What is claimed is:

1. A method of filling a gap comprising:
introducing in a reactor chamber a substrate provided with a gap;
introducing a precursor into the reactor chamber, the precursor comprising silicon, nitrogen, and hydrogen;
introducing a co-reactant into the reactor chamber, wherein the co-reactant is selected from nitrogen, hydrogen, ammonia, hydrazine, one or more noble gasses, and mixtures thereof; and,
generating a plasma in the reactor chamber; whereby the precursor and the co-reactant react in the presence of the plasma to form a gap filling fluid that at least partially fills the gap, the gap filling fluid comprising silicon, nitrogen, and hydrogen.

2. The method according to claim 1, wherein the precursor consists of silicon, nitrogen, and hydrogen, and wherein the gap filling fluid consists of silicon, nitrogen, and hydrogen.

3. The method according to claim 1, wherein the precursor further comprises one or more halogens, and wherein the gap filling fluid further comprises one or more halogens.

4. The method according to claim 3, wherein the precursor consists of silicon, nitrogen, hydrogen, and one or more halogens, and wherein the gap filling fluid consists of silicon, nitrogen, hydrogen, and one or more halogens.

5. The method according to claim 1, wherein the precursor consists of silicon, nitrogen, and hydrogen.

6. The method according to claim 1, wherein the precursor is represented by a chemical formula according to formula (i) 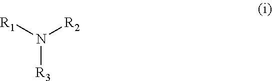
wherein R₁, R₂, and R₃ are independently selected from SiH₃, SiH₂X, SiHXY, SiX₂Y, and SiX₃, wherein X is a first halogen, and wherein Y is a second halogen.

7. The method according to claim 1, wherein the precursor is represented by a chemical formula according to formula (ii) 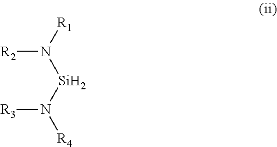
wherein R₁, R₂, R₃, and R₄ are independently selected from H, SiH₃, SiH₂X, SiHXY, SiX₂Y, and SiX₃, wherein X is a first halogen, and wherein Y is a second halogen.

8. The method according to claim 7, wherein at least one of R₁, R₂, R₃, and R₄ is SiH₃.

9. The method according to claim 1, wherein the precursor is represented by a chemical formula according to formula (iii) 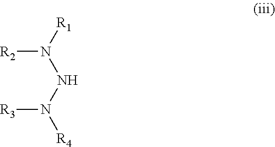
wherein R₁, R₂, R₃, and R₄ are independently selected from SiH₃, SiH₂X, SiHXY, SiX₂Y, and SiX₃, wherein X is a first halogen, and wherein Y is a second halogen.

10. The method according to claim 1, wherein the precursor is a hydrosilazane.

11. The method according to claim 1, wherein the precursor is represented by a chemical formula according to formula (iv) 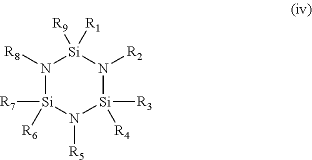
wherein R₁, R₂, R₃, R₄, R₅, R₆, R₇, R₈, and R₉ are independently selected from the list consisting of H, X, Y, NH₂, SiH₃, SiH₂X, SiHXY, SiX₂Y, and SiX₃; wherein X is a first halogen, and wherein Y is a second halogen.

12. The method according to claim 1, wherein the precursor is represented by a chemical formula according to formula (v) 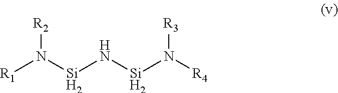
wherein R₁, R₂, R₃, and R₄ are independently selected from SiH₃, SiH₂X, SiHXY, SiX₂Y, and SiX₃, wherein X is a first halogen, and wherein Y is a second halogen.

13. The method according to claim 1, wherein the co-reactant comprises nitrogen and/or ammonia.

14. The method according to claim 1, wherein the co-reactant comprises a noble gas.

15. The method according to claim 1, wherein, at least during the method, the reactor chamber is at a pressure of at least 500 Pa to at most 1500 Pa, and wherein, at least during the method, the reactor chamber is at a temperature of at least 50° C. to at most 150° C.

16. The method according to claim 1, wherein the co-reactant is provided continuously, wherein the precursor is provided in a plurality of precursor pulses, wherein the plasma is provided in a plurality of plasma pulses, and wherein individual precursor pulses and individual plasma pulses are separated by purge steps.

17. The method according to claim 1, wherein the method comprises a step of curing the gap filling fluid.

18. The method according to claim 17, wherein the step of curing involves exposing the gap filling fluid to a direct plasma and the method for filling a gap comprises a plurality of cycles in which gap filling fluid deposition and plasma treatment steps are alternated.

19. The method according to claim 17, wherein the step of curing involves exposing the gap filling fluid to a noble gas plasma.

20. The method according to claim 32, wherein the step of curing involves exposing the gap filling fluid to a micro pulsed plasma comprising the sequential application plasma on pulses and plasma off pulses.
